(19) United States
(12) Patent Application Publication
(10) Pub. No.: US 2019/0296064 A1
(43) Pub. Date: Sep. 26, 2019

(54) PACKAGING METHOD AND PACKAGING STRUCTURE FOR SEMICONDUCTOR CHIP

(71) Applicant: China Wafer Level CSP Co., Ltd., Suzhou, Jiangsu (CN)

(72) Inventors: Zhiqi Wang, Suzhou, Jiangsu (CN); Guoliang Xie, Suzhou, Jiangsu (CN); Hanqing Hu, Suzhou, Jiangsu (CN); Wenbin Wang, Suzhou, Jiangsu (CN)

(73) Assignee: China Wafer Level CSP Co., Ltd., Suzhou, Jiangsu (CN)

(21) Appl. No.: 16/301,726

(22) PCT Filed: May 18, 2017
(86) PCT No.: PCT/CN2017/084862

§ 371 Date: Nov. 14, 2018

(30) Foreign Application Priority Data
May 25, 2016 (CN) 201610351529.7
May 25, 2016 (CN) 201620484861.6

(51) Int. Cl. H01L 27/146; H01L 23/00

(52) U.S. Cl. CPC H01L 27/14618; H01L 27/14687; H01L 27/14632; H01L 27/14636; H01L 24/05; H01L 2224/0231; H01L 2224/02371; H01L 2224/02372; H01L 2224/02381; H01L 2224/05569; H01L 2224/13024; H01L 24/13

(57) ABSTRACT

Provided are a packaging method and packaging structure for a semiconductor chip. The packaging method comprises: providing a wafer, the wafer being provided with multiple semiconductor chips, each semiconductor chip being provided with a functional area and solder pads arranged on a first surface; providing a protective substrate, multiple support units being provided on the protective substrate, openings being formed on the support units; aligning the solder pads to the openings and facing support units provided on the protective substrate to the first surface of the wafer, and pressing together the wafer and the protective substrate. The packaging method effectively prevents the support units from generating stress that acts on the solder pads in a subsequent reliability test, thus preventing cases of the solder pad being damaged or split into layers.

The present application claims priorities to Chinese Patent Application No. 201610351529.7, titled “PACKAGING METHOD AND PACKAGING STRUCTURE FOR SEMICONDUCTOR CHIP”, filed on May 25, 2016 with the Chinese Patent Office, and Chinese Patent Application No. 201620484861.6, titled “PACKAGING STRUCTURE FOR SEMICONDUCTOR CHIP”, filed on May 25, 2016 with the Chinese Patent Office, both of which are incorporated herein by reference in their entireties.

### FIELD

The present disclosure relates to the technical field of semiconductors, and in particular to a wafer level semiconductor chip packaging technology

### BACKGROUND

Currently, the wafer level chip size packaging (WLCSP) technology is the mainstream semiconductor chip packaging technology, in which a full wafer is packaged and tested, and then is cut to acquire individual finished chips. By using this packaging technology, the packaged individual finished chip almost has the same size as an individual crystalline grain, which meets the market requirement for lighter, smaller, shorter, thinner and cheaper microelectronic products. The wafer level chip size packaging technology is a hotspot in the current packaging field and represents a development trend in the future.

The wafer includes multiple semiconductor chips. One surface of the semiconductor chip is arranged with a functional region and contact pads, the contact pads are located on the periphery of the functional region and electrically connected to the functional region. In order to protect the functional region, a protective substrate is laminated with the wafer, and the protective substrate is provided with support units. Since the support unit is in contact with the wafer at a position corresponding to each of the contact pads and the thermal expansion coefficient of the support unit is different from that of the wafer, the support unit may generate a stress acting on the contact pad during a reliability test, which may easily cause a damage to the contact pad. In particular, in a case that the contact pad has a multi-layer structure, the stress may easily cause delamination of the contact pad.

### SUMMARY

A wafer level semiconductor chip packaging method and a semiconductor chip package are provided according to the present disclosure, to solve the problem that the contact pad may be damaged, so as to improve the quality and reliability of the semiconductor chip package.

In order to solve the above problem, a semiconductor chip packaging method is provided according to the present disclosure, which includes:
providing a wafer having a first surface and a second surface opposite to each other, where the wafer includes multiple semiconductor chips, and each of the multiple semiconductor chips includes a functional region and contact pads arranged on the first surface;
providing a protective substrate, where one surface of the protective substrate is arranged with multiple support units, and each of the multiple support units is provided with openings; and
laminating the wafer with the protective substrate in a manner that each of the contact pads is aligned with one opening and each of the multiple support units on the protective substrate is arranged facing the first surface of the wafer.

In an embodiment, the multiple semiconductor chips are arranged in a grid. The multiple support units are located in one-to-one correspondence with the multiple semiconductor chips. In addition/Alternatively, the functional region of each of the multiple semiconductor chips is located in a sealed cavity formed by surrounding the support unit corresponding to the semiconductor chip.

In an embodiment, before the laminating the wafer with the protective substrate, the method further includes:
forming the openings in the support unit, where the first surface of the wafer is not in contact with the support unit at a position corresponding to each of the contact pads.

In an embodiment, the support unit is made of photosensitive glue, and the support unit and the openings in the support unit are simultaneously formed by an exposure development process.

In an embodiment, the multiple support units are arranged in a grid, and the openings are formed by a laser drilling process after the multiple support units arranged in a grid are formed.

In an embodiment, after the laminating the wafer with the protective substrate, the method further includes:
forming multiple through holes on the second surface of the wafer, where the multiple through holes are located in one-to-one correspondence with the contact pads, and each of the contact pads is exposed from a bottom of one through hole;
forming a metal wiring layer at a bottom and a sidewall of each of the multiple through holes, where the metal wiring layer is extended to the second surface of the wafer and is electrically connected to the contact pads;
forming a solder resist layer covering the second surface of the wafer, where each of the multiple through holes is filled with the solder resist layer and a groove is formed on the solder resist layer at a position corresponding to the through hole;
providing openings on the solder resist layer, where the metal wiring layer is exposed from a bottom of each of the openings; and
forming one solder bump in each of the openings, where the solder bump is electrically connected to the metal wiring layer.

In an embodiment, the solder resist layer is formed by a spray coating process, and the sidewall and the bottom of the through hole are uniformly covered by the solder resist layer.

In an embodiment, the solder resist layer is formed on the second surface of the wafer and in each of the multiple through holes by a spin coating process. The groove is formed on the solder resist layer at the position corresponding to the through hole by an etching process or a laser drilling process.

In an embodiment, a difference between a depth of the groove and a depth of the through hole arranges from 0 to 20 micrometers, and the solder resist layer is made of photosensitive glue.

In an embodiment, after the laminating the wafer with the protective substrate, the method further includes:
forming multiple through holes on the second surface of the wafer, where the multiple through holes are located in one-to-one correspondence with the contact pads, and each of the contact pads is exposed from a bottom of one through hole;
forming a metal wiring layer at a bottom and a sidewall of each of the multiple through holes, where the metal wiring layer is extended to the second surface of the wafer and is electrically connected to the contact pads;
forming a solder resist layer covering the second surface of the wafer, where the multiple through holes are covered by the solder resist layer to form a cavity in each of the multiple through holes;
providing openings on the solder resist layer, where the metal wiring layer is exposed from a bottom of each of the openings; and
forming one solder bump in each of the openings, where the solder bump is electrically connected to the metal wiring layer.

In an embodiment, the solder resist layer is formed by a spin coating process, and a viscosity of the solder resist layer is greater than 12 Kcps.

In an embodiment, the semiconductor chip is an image sensor chip, and the functional region is arranged with a photosensitive element.

A semiconductor chip package is further provided according to the present disclosure, which includes: a substrate having a first surface and a second surface opposite to each other; a functional region and contact pads arranged on the first surface of the substrate; a protective substrate arranged on the first surface of the substrate; and a support unit arranged between the protective substrate and the substrate. The functional region is arranged in a sealed cavity formed by surrounding the support unit. The support unit is provided with openings, such that the first surface of the wafer is not in contact with the support unit at a position corresponding to each of the contact pads.

In an embodiment, the support unit is made of photosensitive glue.

In an embodiment, the package further includes:
through holes located in one-to-one correspondence with the contact pads and arranged on the second surface of the substrate, where each of the contact pads is exposed from a bottom of one through hole;
a metal wiring layer arranged at a bottom of each of the through holes and on a sidewall of each of the through holes, where the metal wiring layer is extended to the second surface of the substrate and is electrically connected to the contact pads;
a solder resist layer covering the second surface of the substrate, where each of the through holes is filled with the solder resist layer and a groove is formed on the solder resist layer at a position corresponding to the through hole;
openings arranged on the solder resist layer, where the me wiring layer is exposed from a bottom of each of the openings; and
solder bumps each of which is arranged in one opening, where the solder bumps are electrically connected to the metal wiring layer.

In an embodiment, the sidewall and the bottom of each of the through holes are covered by the solder resist layer.

In an embodiment, a difference between a depth of the groove and a depth of the through hole arranges from 0 to 20 micrometers, and the solder resist layer is made of photosensitive glue.

In an embodiment, the semiconductor chip package further includes:
through holes located in one-to-one correspondence with the contact pads and arranged on the second surface of the substrate, where each of the contact pads is exposed from a bottom of one through hole;
a metal wiring layer arranged at a bottom of each of the through holes and on a sidewall of each of the through holes, where the metal wiring layer is extended to the second surface of the substrate and is electrically connected to the contact pads;
a solder resist layer covering the second surface of the substrate, where the multiple through holes are covered by the solder resist layer to form a cavity in each of the multiple through holes;
openings arranged on the solder resist layer, where the metal wiring layer is exposed from a bottom of each of the openings; and
solder bumps each of which is arranged in one opening, where the solder bumps are electrically connected to the metal wiring layer

In an embodiment, a viscosity of the solder resist layer is greater than 12 Kcps.

In an embodiment, the semiconductor chip is an image sensor chip, and the functional region is arranged with a photosensitive element.

According to the present disclosure, the following beneficial effect can be achieved. The support unit is provided with openings, such that the wafer is not in contact with the support unit at a position corresponding to each of the contact pads, thereby effectively preventing the support unit from generating a stress acting on the contact pad in a subsequent reliability test, thus avoiding a damage to the contact pad or delamination of the contact pad. In this way, the packaging yield of the semiconductor chip is improved and the reliability of the semiconductor chip package is also improved.

### BRIEF DESCRIPTION OF THE DRAWINGS

FIG. 1 is a schematic diagram of a wafer level semiconductor chip package;

FIG. 2 is a schematic diagram of structure of a wafer level semiconductor chip;

FIG. 3 is a schematic cross-sectional view of a wafer level semiconductor chip package according to an embodiment of the present disclosure;

FIGS. 4 to 11 are schematic diagrams showing a wafer level semiconductor chip packaging method according to an embodiment of the present disclosure; and

FIG. 12 is a schematic diagram of an individual semiconductor chip package according to an embodiment of the present disclosure.

### DETAILED DESCRIPTION OF EMBODIMENTS

The embodiments of the present disclosure are described in detail below in conjunction with the drawings. However, the embodiments are not intended to limit the present disclosure, and any changes in structures, methods or functions made by those skilled in the art based on the embodiments fall within the protection scope of the present disclosure.

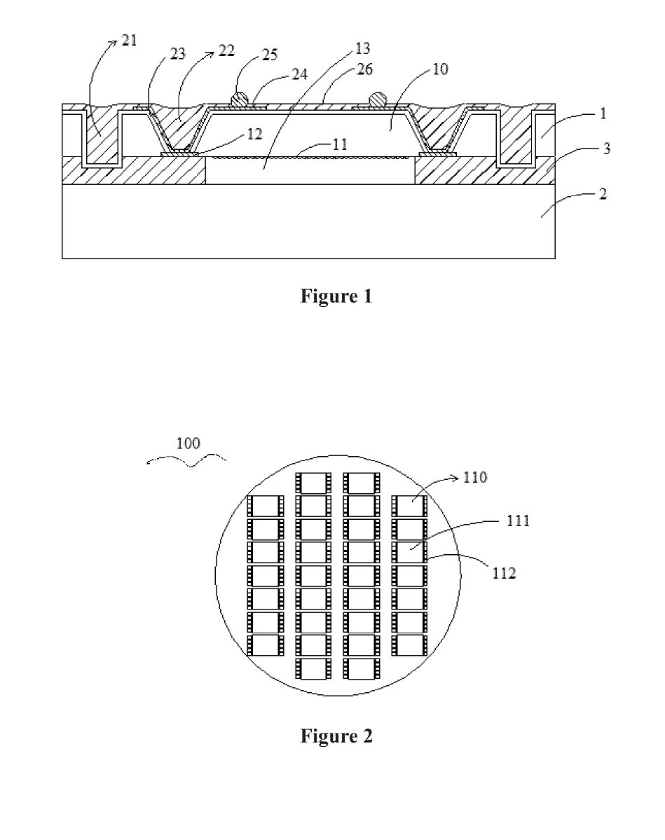

Generally, the semiconductor chip is integrated with sensitive elements, and it is required to protect the sensitive elements on the semiconductor chip during the semiconductor chip is packaged. Referring to FIG. 1, a water level semiconductor chip package is shown. A wafer 1 includes multiple semiconductor chips 10 arranged in a grid. One surface of each of the semiconductor chips 10 is arranged with a functional region 11 and contact pads 12. The contact pads 12 are located on the periphery of the functional region 11 and electrically connected to the functional region 11. Since the functional region is integrated with sensitive elements, a protective substrate 2 is laminated with the wafer 1 to protect the functional region 11. The protective substrate 2 is provided with multiple support units 3 arranged in a grid, which are located in one-to-one correspondence with the semiconductor chips 10. 1n a case that the wafer 1 is aligned and laminated with the protective substrate 2, the support unit 3 is located between the wafer 1 and the protective substrate 2, such that a gap is formed between the wafer 1 and the protective substrate 2, thereby avoiding a direct contact between the protective substrate 2 and the wafer 1. The functional region 11 is located in a sealed cavity 13 formed by surrounding the support unit 3.

Since the contact pad 12 and the functional region 11 are located on the first surface of the wafer 1, in order to implement an electrical connection between the contact pad 12 and an external circuit, a solder bump 25 electrically connected to the contact pad 12 is formed on the second surface of the wafer 1 by TSV or TSL process after the wafer 1 is aligned and laminated with the protective substrate 2, and the electrical connection between the contact pad 12 and the external circuit may be implemented. by electrically connecting the solder hump 25 to the external circuit.

In order to implement the electrical connection between the contact pad 12 and the external circuit, through holes 22 extending toward the first surface of the water 1 are arranged on the second surface of the wafer 1. The through holes 22 are located in one-to-one correspondence with the contact pads 12, and each of the contact pads 12 is exposed from a bottom of one through hole 22. An insulating layer 23 is arranged on a sidewall of each of the through holes 22 and the second surface of the wafer 1. A metal wiring layer 24 is arranged on the insulating layer 23 and the bottom of each of the through holes 22. The metal wiring layer 24 is electrically connected to the contact pads 12. Solder bumps 25 are arranged on the second surface of the wafer, and the solder bumps 25 are electrically connected to the metal wiring layer 24. The second surface of the wafer 1 is arranged with cutting trenches 21 extending toward the first surface of the wafer 1, to facilitate cutting off the packaged sensor chip tin an example, the sensor chip is an image sensor chip).

Since the thermal expansion coefficient of the support unit 3 is different from that of the wafer 1, the support unit 3 may generate a stress acting on the contact pad 12 in the subsequent reliability test, which may cause a damage to the contact pad 12. In particular, in a case that the contact pad 12 has a multi-layer structure, the stress of the support unit 3 acting on the contact pad 12 may cause delamination of the contact pad 12.

In order to solve the problem of the damage to the contact pad and/or the delamination of the contact pad, in the embodiment of the present disclosure, the support unit is provided with openings, such that the wafer is not in contact with the support unit at a position corresponding to each of the contact pads, thereby effectively preventing the support unit from generating a stress acting on the contact pad in a subsequent reliability test, thus avoiding the damage to the contact pad or the delamination of the contact pad. In this way, the packaging yield of the semiconductor chip is improved and the reliability of the semiconductor chip package is also improved.

Reference is made to FIG. 2, which is a schematic diagram of a structure of a wafer level semiconductor chip. A wafer 100 includes multiple semiconductor chips 110 arranged in a gird. There is a gap reserved between adjacent semiconductor chips 110. After the packaging process and the testing process are completed, the semiconductor chips are separated from each other along the gaps.

Each of the semiconductor chips 110 includes a functional region 111 and multiple contact pads 112. The contact pads are arranged on the periphery of the functional region 111. In addition, the contact pads 112 and the functional region 111 are arranged on the same surface of the wafer 100.

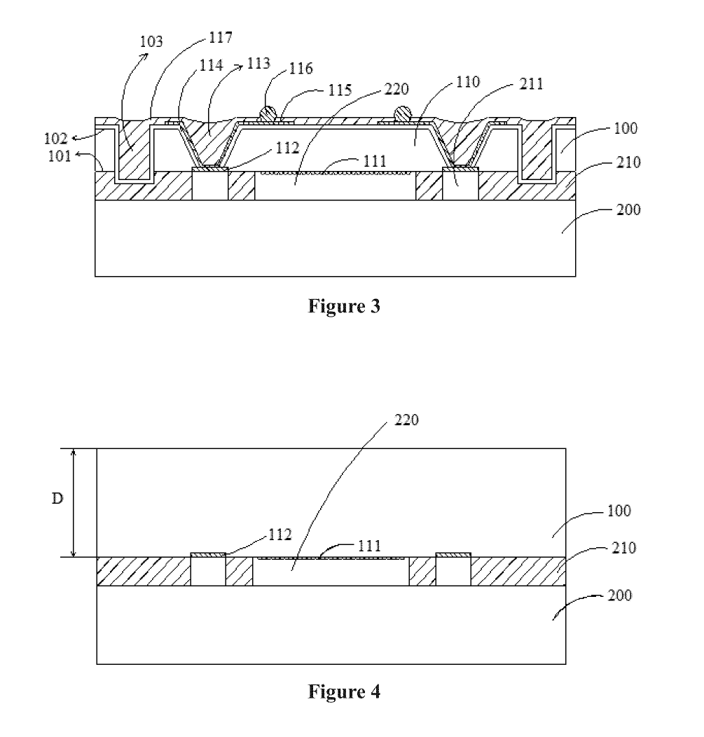

Reference is made to FIG. 3, which is a schematic cross-sectional view of a wafer level semiconductor chip package according to an embodiment of the present disclosure. One surface of a protective substrate 200 is arranged with multiple support units 210 in a grid. In a case that the wafer 100 is aligned and laminated with the protective substrate 200, the support unit 210 is located between the wafer 100 and the protective substrate 200, such that a gap is formed between the wafer 100 and the protective substrate 200. The support units 210 are located in one-to-one correspondence with the semiconductor chips 110. The functional region 111 is located in a sealed cavity 220 formed by surrounding the support unit 3.

The wafer 100 has a first surface 101 and a second surface 102 opposite to each other. The functional region 111 and the contact pads 112 are arranged on the first surface 101 of the wafer 100. The second surface 102 of the wafer is arranged with cutting trenches 103 and through holes 113. The cutting trench 103 and the through hole 113 are extended toward the first surface 101. Each of the through holes 113 corresponds to one contact pad 112 in terms of position, and the contact pad 112 is exposed from the bottom of the through hole 113.

The electrical connection between the contact pad 112 and the external circuit is implemented via the metal wiring layer 115 and the solder bump 116. Specifically, an insulating layer 114 is arranged on the sidewall of the through hole 113 and the second surface 102 of the wafer 100, a metal wiring layer 115 electrically connected to the contact pads 112 is formed at the bottom of each of the through holes 113 and on the sidewall of each of the through holes 113. The metal wiring layer 115 is extended to the second surface 102 of the wafer 100. The metal wiring layer 115 is arranged on the insulating layer 114, and a solder resist layer 117 is arranged on the metal wiring layer 115. The solder resist layer 117 covers the second surface 102 of the wafer 100 and fills the cutting trenches 103 and the through holes 113. The solder resist layer 117 is provided with openings, and the metal wiring layer 115 is exposed from the bottom of each of the openings. The solder bump 116 is arranged in each of the openings and is electrically connected to the metal wiring layer 115. The electrical connection between the contact pad 112 and the external circuit is implemented by electrically connecting the solder bump 116 to the external circuit.

The support unit 210 is provided with openings 211, such that the wafer 100 is not in contact with the support unit 210 at a position corresponding to each of the contact pads 112, thereby effectively preventing the support unit 210 from generating a stress acting on the contact pad 112 in a subsequent reliability test, thus avoiding a. damage to the contact pad 112 or delamination of the contact pad 112. In this way, the packaging yield of the semiconductor chip is improved and the reliability of the semiconductor chip package is also improved.

A packaging process for forming a semiconductor chip package as shown in FIG. 3 is described as follows.

The wafer 100 is provided. Reference may he made to FIG. 2 for a schematic diagram of a structure of the wafer 100.

The protective substrate 200 is provided. One surface of the protective substrate 200 is arranged with the multiple support units 210 in a grid. In the embodiment, the support unit 210 is made of photosensitive glue. The support units 210 and the openings 211 are simultaneously formed on the surface of the protective substrate 200 by coating the entire surface of the protective substrate 200 with the photosensitive glue and then using an exposure development process.

Alternatively, the support units 210 arranged in a grid and the openings 211 are simultaneously formed on one surface of the protective substrate 200 by a screen printing process.

Alternatively, the support units 210 are first formed by an exposure development process, and the opening 211 is formed on the support unit 210 at a position corresponding to each of the contact pads 112 by a laser drilling process.

Alternatively, the support units 210 are first formed by a screen printing process, and the opening 211 is formed on the support unit 210 at a position corresponding to each of the contact pads 112 by a laser drilling process.

Referring to FIG. 4, the wafer 100 is aligned and laminated with the protective substrate 200, and the wafer 100 is bonded to the protective substrate 200 with an adhesive. The support unit 210 is located between the wafer 100 and the protective substrate 200. The support units 210 are located in one-to-one correspondence with the semiconductor chips 110. The functional region 111 of the semiconductor chip 110 is located in a sealed cavity 220 formed by surrounding the support unit 210.

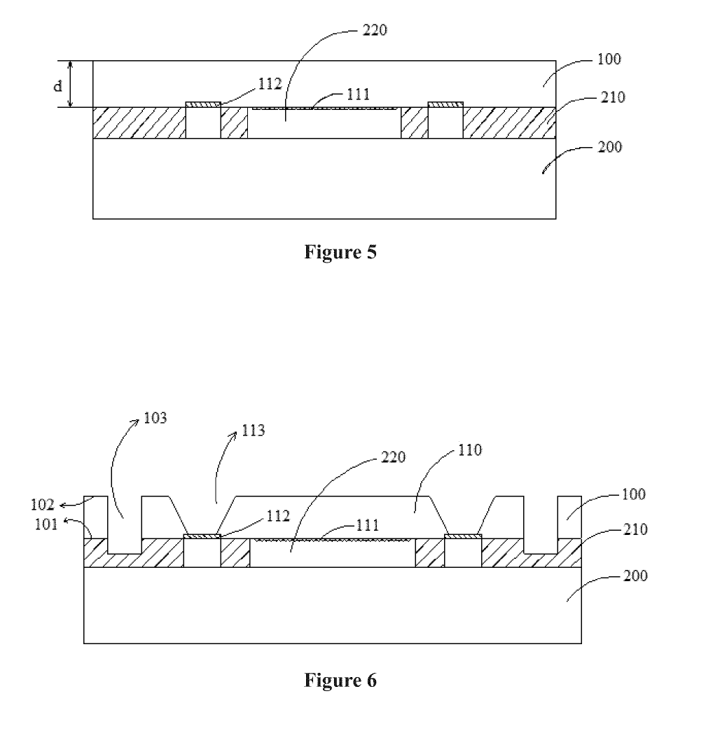

Referring to FIG. 5, the wafer 100 is grinded and thinned on the second surface 102. A thickness of the wafer 100 before thinning is denoted as D (referring to FIG. 4), and a thickness of the wafer 100 after thinning is denoted as d.

Referring to FIG. 6, cutting trenches 103 are formed on the second surface 102 of the wafer 100 by a cutting process. The cutting trench 103 is partially extended into the support unit 210 but does not penetrate the support unit 210. The through holes 113 are formed on the second surface 102 of the wafer 100 by an etching process. The contact pad 112 is exposed from the bottom of the through hole 113.

In another embodiment of the present disclosure, the through holes 113 may be first formed and then the cutting trenches 103 are formed.

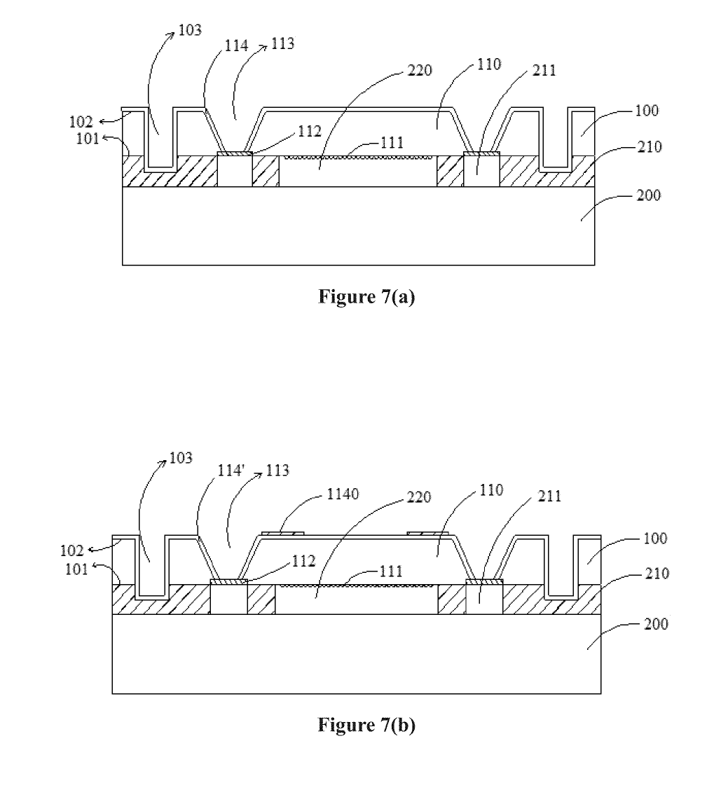

Referring to FIG. 7(a), the insulating layer 114 is formed on the second surface 102 of the wafer 100, on a sidewall of each of the through holes 113, at the bottom of each of the through holes 113, on a sidewall of each of the cutting trenches 103, and at the bottom of each of the cutting trenches 103. In the embodiment, the insulating layer 114 is made of an organic insulating material, thus the insulating layer 114 has insulativity and flexibility. The insulating layer 114 is formed by a spraying or spin-coating process, and then the contact pad 112 is exposed from the insulating layer 114 by means of laser or by an exposing and developing process.

Referring to FIG. 7 (b), an insulating layer 114′ may be deposited on the second surface 102. of the wafer 100, on the sidewall of each of the through holes 113, at the bottom of each of the through holes 113, on the sidewall of each of the cutting trenches 103, and at the bottom of each of the cutting trenches 103. The insulating layer 114′ is made of an inorganic material, which normally is silicon dioxide. Preferably, since impact resistance of the silicon dioxide is not as good as that of the organic insulating material, a buffer layer 1140 is formed on the second surface of the wafer 101 by an exposing and developing process to facilitate subsequent formation of solder bumps. Then the insulating layer at the bottom of the through hole 113 is etched off by an etching process to expose the contact pad

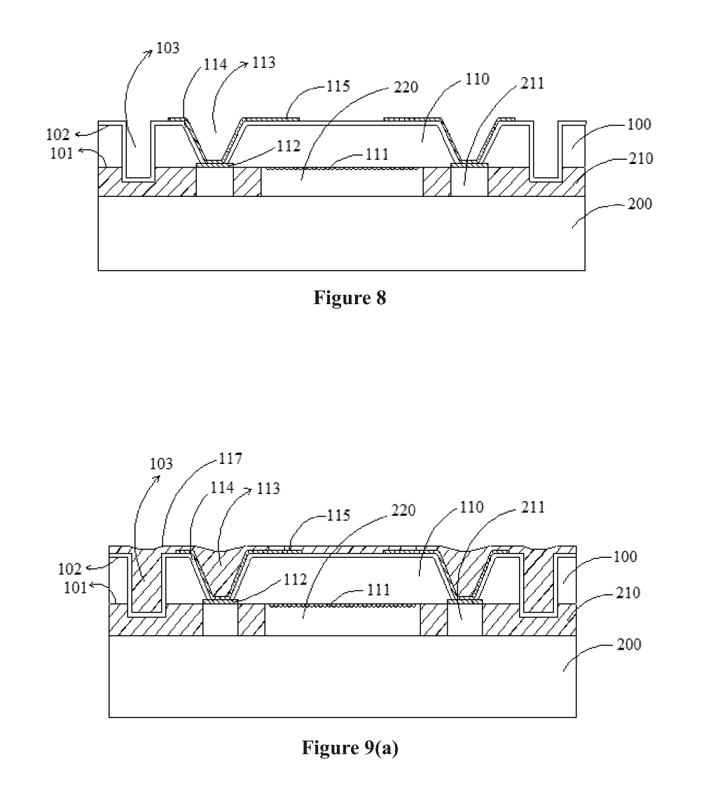

Referring to FIG. 8, a metal wiring layer 115 is formed on the insulating layer 114 (or the insulating layer 114′). The metal wiring layer 115 covers the sidewall and the bottom of each of the through holes 113 and is extended to the second surface 102 of the wafer 100. The metal wiring layer 115 is electrically connected to the contact pads 112. Preferably, a thickness of the metal wiring layer 115 ranges from 1 micrometer to 5 micrometers.

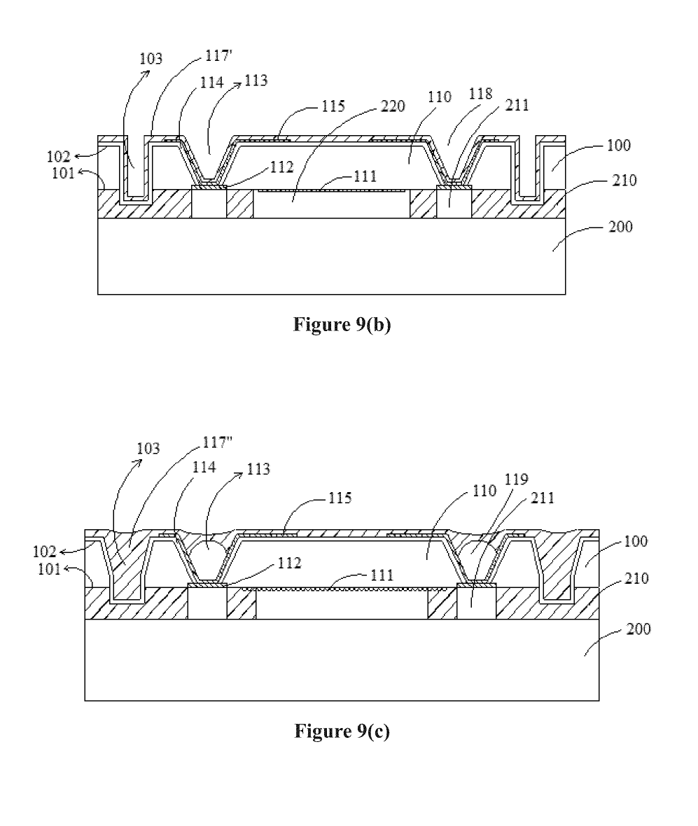

Referring to FIG. 9(a), a solder resist layer 117 is formed in the cutting trenches 103, in the through holes 113 and on the second surface 102 of the water by a spin coating process to facilitate the subsequent solder ball process, which acts as a solder mask and protects the chip.

Referring to FIG. 9(b), in another embodiment of the present disclosure, a solder resist layer 117′ with an uniform thickness is formed on the sidewall of each of the cutting trenches 103, at the bottom of each of the cutting trenches 103, on the sidewall of each of the through holes 113, at the bottom of each of the through holes 113, and on the second surface 102 of the wafer 100 by a spraying process. Since the solder resist layer 117′ has an uniform thickness, a groove 118 is formed on the solder resist layer 117′ at a position corresponding to each of the through holes 113, such that the amount of the solder resist layer 117′ filled in the through holes 113 is reduced, thereby reducing the stress of the solder resist layer 117′ acting on the metal wiring layer 115 in the subsequent reflow solder process and reliability test, thus preventing delamination of the contact pad 112 from the metal wiring layer 115.

Preferably, a thickness of the solder resist layer 117′ ranges from 5 micrometers to 20 micrometers.

However, the groove may be formed on the solder resist layer 117 at the position corresponding to each of the through holes 113 by an etching process or a laser drilling process after the spraying process shown in FIG. 9(a).

The difference between the depth of the groove (for example, the groove and the depth of the through hole 113 ranges from 0 to 20 micrometers.

Referring to FIG. 9(c), in another embodiment of the present disclosure, in order to prevent the delamination of the contact pad 112 from the metal wiring layer 115, a solder resist layer 117″ is formed on the second surface 102 of the wafer 100 by a spin coating process. The through holes 113 are covered by the solder resist layer 117″ to form a cavity 119 in each of the through holes 113, such that the contact area of the solder resist layer 117″ with the through hole 113 is reduced, thereby avoiding the stress of the solder resist layer 117″ acting on the metal wiring layer 115 in the subsequent reflow soldering process and reliability test, thus preventing the delamination of the contact pad 112 from the metal wiring layer 115.

Preferably, a viscosity of the solder resist layer 117″ is greater than 12 Kcps.

Preferably, in order to form the cavity 119 in the through hole 113, it is required to increase the rate of spin coating process. In order to fill the cutting trench 103 with the soldering layer 117″, the sidewall of the cutting trench 103 is arranged to be an inclined surface to facilitate the filling of the solder resist layer 117″.

In the embodiment, the solder resist layers 117, 117′ and/or 117″ may be made of photosensitive glue.

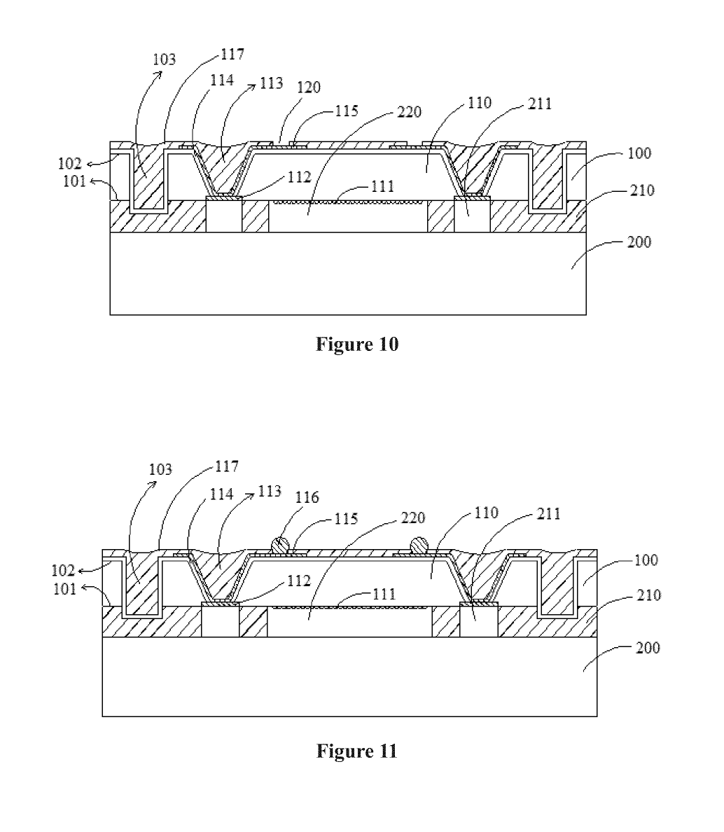

Referring to FIG. 10, openings 120 are formed on the second surface of the wafer 100 by an exposure development process, and the metal wiring layer 115 is exposed from the bottom of each of the openings 120.

Referring to FIG. 11, the solder bump 116 is formed in each of the openings 120 by a solder ball process, such that the solder bump 116 is electrically connected to the metal wiring layer 115.

Finally, the wafer 100 and the protective substrate 200 are cut from the second surface 102 of the wafer 100 towards the first surface 101 of the wafer 100 along the cutting trenches 103 to acquire individual semiconductor chip packages.

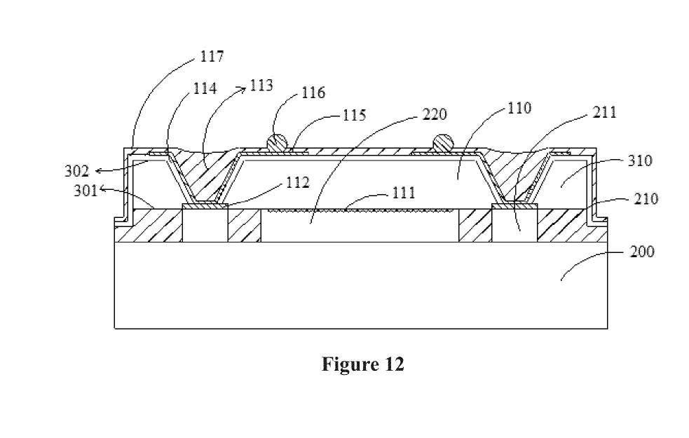

Referring to FIG. 12, an individual semiconductor chip package includes a substrate 310 obtained by cutting the wafer 100. The substrate 310 has a first surface 301 and a second surface 302 opposite to each other. The functional region 111 and the contact pads 112 are arranged on the first surface 301. The through holes 113 and the solder bumps 116 are arranged on the second surface 302. The sidewall of the substrate 310 is covered by the solder resist layer 117.

The support unit 210 is provided with openings 211, such that the substrate 310 is not in contact with the support unit 210 at a position corresponding to each of the contact pads 112, thereby effectively preventing the support unit 210 from generating a stress acting on the contact pad 112 in a subsequent reliability test, thus preventing a damage to the contact pad 112 or delamination of the contact pad 112. In this way, the packaging yield of the semiconductor chip is improved and the reliability of the semiconductor chip package is also improved.

The semiconductor chip in the embodiment may be an image sensor chip, and the functional region is arranged with a photosensitive element. However, the semiconductor chip in the embodiment of the present disclosure is not limited to the image sensor chip.

According to the present disclosure, the following beneficial effect can be achieved. The support unit is provided with openings, such that the wafer is not in contact with the support unit at a position corresponding to each of the contact pads, thereby effectively preventing the support unit from generating a stress acting on the contact pad in a subsequent reliability test, thus avoiding a damage to the contact pad or delamination of the contact pad. In this way, the packaging yield of the semiconductor chip is improved and the reliability of the semiconductor chip package is also improved.

It is to be understood that although the specification is described according to the embodiments, not each of the embodiments includes only one independent technical solution. The description of the specification is merely for the sake of clarity and those skilled in the art should take the specification as a whole, and the technical solutions in the embodiments may also be appropriately combined to form other embodiments that can be understood by those skilled in the art.

A series of detailed description above merely illustrates the feasible embodiments of the present disclosure, and is not intended to limit the protection scope of the present disclosure. Any equivalent embodiment or variation made without departing from the technical spirit of the present disclosure should fall within the protection scope of the present disclosure.

1. A semiconductor chip packaging method, comprising:
providing a wafer having a first surface and a second surface opposite to each other, wherein the wafer comprises a plurality of semiconductor chips, and each of the plurality of semiconductor chips comprises a functional region and contact pads arranged on the first surface;
providing a protective substrate, wherein one surface of the protective substrate is arranged with a plurality of support units, and each of the plurality of support units is provided with openings; and
laminating the wafer with the protective substrate in a manner that each of the contact pads is aligned with one opening and each of the plurality of support units on the protective substrate is arranged facing the first surface of the wafer.

2. The semiconductor chip packaging method according to claim 1, wherein
the plurality of semiconductor chips are arranged in a grid,
the plurality of support units are located in one-to-one correspondence with the plurality of semiconductor chips, and/or
the functional region of each of the plurality of semiconductor chips is located in a sealed cavity formed by surrounding the support unit corresponding to the semiconductor chip.

3. The semiconductor chip packaging method according to claim 1, wherein before the laminating the wafer with the protective substrate, the method further comprises:
forming the openings in the support unit, wherein the first surface of the wafer is not in contact kith. the support unit at a position corresponding to each of the contact pads.

4. The semiconductor chip packaging method according to claim 1, wherein the support unit is made of photosensitive glue, and the support unit and the openings in the support unit are simultaneously formed by an exposure development process.

5. The semiconductor chip packaging method according to claim 1, wherein the plurality of support units are arranged in a grid, and the openings are formed by a laser drilling process after the plurality of support units arranged in a grid are formed.

6. The semiconductor chip packaging method according to claim 1, after the laminating the wafer with the protective substrate, the method further comprises:
forming a plurality of through holes on the second surface of the wafer, wherein the plurality of through holes are located in one-to-one correspondence with the contact pads, and each of the contact pads is exposed from a bottom of one through hole;
forming a metal wiring layer at a bottom and a sidewall of each of the plurality of through holes, wherein the metal wiring layer is extended to the second surface of the wafer and is electrically connected to the contact pads;
forming a solder resist layer covering the second surface of the wafer, wherein each of the plurality of through holes is filled with the solder resist layer, and a groove is formed on the solder resist layer at a position corresponding to the through hole;
providing openings on the solder resist layer, wherein the metal wiring layer is exposed from a bottom of each of the openings; and
forming one solder bump in each of the openings, wherein the solder bump is electrically connected to the metal wiring layer.

7. The semiconductor chip packaging method according to claim 6, wherein the solder resist layer is formed by a spray coating process, and the sidewall and the bottom of the through hole are uniformly covered by the solder resist layer.

8. The semiconductor chip packaging method according to claim 6, wherein the solder resist layer is formed on the second surface of the wafer and in each of the plurality of through holes by a spin coating process; the groove is formed on the solder resist layer at the position corresponding to the through hole by an etching process or a laser drilling process.

9. The semiconductor chip packaging method according to claim 6, wherein a difference between a depth of the groove and a depth of the through hole arranges from 0 to 20 micrometers, and the solder resist layer is made of photosensitive glue.

10. The semiconductor chip packaging method according to claim 1, after the laminating the wafer with the protective substrate, the method further comprises:
forming a plurality of through holes on the second surface of the wafer, wherein the plurality of through holes are located in one-to-one correspondence with the contact pads, and each of the contact pads is exposed from a bottom of one through hole;
forming a metal wiring layer at a bottom and a sidewall of each of the plurality of through holes, wherein the metal wiring layer is extended to the second surface of the wafer and is electrically connected to the contact pads;
forming a solder resist layer covering the second surface of the wafer, wherein the plurality of through holes are covered by the solder resist layer to form a cavity in each of the plurality of through holes;
providing openings on the solder resist layer, wherein the metal wiring layer is exposed from a bottom of each of the openings; and
forming one solder bump in each of the openings, wherein the solder bump is electrically connected to the metal wiring layer.

11. The semiconductor chip packaging method according to claim 10, wherein the solder resist layer is formed by a spin coating process, and a viscosity of the solder resist layer is greater than 12 Kcps.

12. The semiconductor chip packaging method according to claim 1, wherein the semiconductor chip is an image sensor chip, and the functional region is arranged with a photosensitive element.

13. A semiconductor chip package, comprising:
a substrate having a first surface and a second surface opposite to each other;
a functional region and contact pads arranged on the first surface of the substrate;
a protective substrate arranged on the first surface of the substrate; and
a support unit arranged between the protective substrate and the substrate, wherein the functional region is arranged in a sealed cavity formed by surrounding the support unit, and the support unit is provided with openings, wherein a first surface of a wafer is not in contact with the support unit at a position corresponding to each of the contact pads.

14. The semiconductor chip package according to claim 13, wherein the support unit is made of photosensitive glue.

15. The semiconductor chip package according to claim 13, further comprising:
through holes located in one-to-one correspondence with the contact pads and arranged on the second surface of the substrate, wherein each of the contact pads is exposed from a bottom of one through hole;
a metal wiring layer arranged at a bottom of each of the through holes and on a sidewall of each of the through holes, wherein the metal wiring layer is extended to the second surface of the substrate and is electrically connected to the contact pads;
a solder resist layer covering the second surface of the substrate, wherein each of the through holes is filled with the solder resist layer and a groove is formed on the solder resist layer at a position corresponding to the through hole;
openings arranged on the solder resist layer, wherein the metal wiring layer is exposed from a bottom of each of the openings; and
solder bumps each of which is arranged in one opening, wherein the solder bumps are electrically connected to the metal wiring layer.

16. The semiconductor chip package according to claim 15, wherein the sidewall and the bottom of each of the through holes are covered by the solder resist layer.

17. The semiconductor chip package according to claim 15, wherein a difference between a depth of the groove and a depth of the through hole arranges from 0 to 20 micrometers, and the solder resist layer is made of photosensitive glue.

18. The semiconductor chip package according to claim 13, further comprising:
through holes located in one-to-one correspondence with the contact pads and arranged on the second surface of the substrate, wherein each of the contact pads is exposed from a bottom of one through hole;
a metal wiring layer arranged at a bottom of each of the through holes and on a sidewall of each of the through holes, wherein the metal wiring layer is extended to the second surface of the substrate and is electrically connected to the contact pads;
a solder resist layer covering the second surface of the substrate, wherein the plurality of through holes are covered by the solder resist layer to form a cavity in each of the plurality of through holes;
openings arranged on the solder resist layer, wherein the metal wiring layer is exposed from a bottom of each of the openings; and
solder bumps each of which is arranged in one opening, wherein the solder bumps are electrically connected to the metal wiring layer.

19. The semiconductor chip package according to claim 18, wherein a viscosity of the solder resist layer is greater than 12 Kcps.

20. The semiconductor chip package according to claim 13, wherein the semiconductor chip is an image sensor chip and the functional region is arranged with a photosensitive element.
